(19) United States
(12) Patent Application Publication
(10) Pub. No.: US 2024/0014185 A1
(43) Pub. Date: Jan. 11, 2024

(54) LED ARRANGEMENT STRUCTURES

(71) Applicant: Jiangxi MTC Visual Display Co., Ltd, Nanchang (CN)

(72) Inventors: Haibo ZHANG, Shenzhen (CN); Shengbin HE, Shenzhen (CN); Wei GU, Shenzhen (CN)

(21) Appl. No.: 18/220,201

(22) Filed: Jul. 10, 2023

Related U.S. Application Data
(63) Continuation of application No. PCT/CN2022/110067, filed on Aug. 3, 2022.

(30) Foreign Application Priority Data
Jul. 5, 2022 (CN) 202210792762.4

(51) Int. Cl. H01L 25/075

(52) U.S. Cl. CPC H01L 25/0753

(57) ABSTRACT

An LED arrangement structure is provided with a plurality of LEDs arranged in an array in the first direction and the second direction to form a plurality of LED rows and a plurality of LED columns, each of the LED rows includes a plurality of LED groups, and each of the LED groups includes two adjacent LEDs. Two non-common-electrode terminals in each of LED groups in at least one of the LED rows are connected to each other on a surface layer of the PCB board.

### CROSS-REFERENCE TO RELATED APPLICATION

This application is a continuation of International Application No. PCT/CN2022/110067 having international filing date of Aug. 3, 2022, which claims priority to and the benefit of Chinese Patent Application No. 202210792762.4 filed on Jul. 5, 2022. The contents of the above applications are all incorporated by reference as if fully set forth herein in their entireties.

### TECHNICAL FIELD

The present disclosure relates to a field of LED (light-emitting diode) display technology, and more particularly, to LED arrangement structures.

### BACKGROUND

An LED display screen is a planar multimedia display terminal composed of a light-emitting diode dot matrix module or a pixel unit, which has the characteristics of high brightness, wide visual range, long service life, low cost, and the like.

Currently, in the design and production process of an LED display screen, it is generally necessary to perforate a PCB board, or increase the width of the PCB board, or increase the number of layers of the PCB board. However, too many holes on the PCB board can easily increase the defect rate of the PCB board, and increasing the width or the number of layers of the PCB board can greatly increase the material cost, thereby greatly increasing the production cost of the LED display screen. Therefore, how to improve the yield of PCB boards to reduce the production cost of the PCB board has become a technical problem urgently to be solved at present.

### SUMMARY

An embodiment of the present disclosure provides an LED arrangement structure including: a PCB board, a plurality of data lines extending in a first direction, a plurality of scanning lines extending in a second direction, and a plurality of via holes are disposed in a display region of the PCB board; the plurality of data lines and the plurality of scanning lines are located on different layers of the PCB board, and the second direction intersects the first direction; and the plurality of via holes include a plurality of first via holes and a plurality of second via holes; a plurality of LEDs disposed on the PCB board, wherein the plurality of LEDs are arranged in an array in the first direction and the second direction to form a plurality of LED rows and a plurality of LED columns, the LED rows extend in the first direction, and the LED columns extend in the second direction; each of the LED rows includes a plurality of LED groups, and each of the LED groups includes two adjacent LEDs; a plurality of adjacent LEDs are sequentially arranged in the second direction to form a plurality of light-emitting pixels; and each of the LEDs includes a common-electrode terminal and a non-common-electrode terminal; common-electrode terminals of all LEDs in each of the LED columns are connected to a corresponding one of the scanning lines through one or more first via holes of the first via holes; non-common-electrode terminals of all LEDs in each of the LED rows are connected to a corresponding one of the data lines; and non-common-electrode terminals of two LEDs in each of LED groups in at least one of the LED rows are connected to each other on a surface layer of the PCB board.

Meanwhile, an embodiment of the present disclosure provides an LED arrangement structure including a PCB board for mounting a plurality of LEDs, and the PCB board includes: M data lines extending in a first direction, wherein M≥3 and is an integer; N scanning lines extending in a second direction, wherein N≥2 and is an integer; and the second direction intersects the first direction; and a plurality of terminal pairs, wherein each of the terminal pairs includes a first terminal and a second terminal, the plurality of terminal pairs form M rows of terminal pairs and N columns of terminal pairs, first terminals of all terminal pairs in an i-th row of terminal pairs are connected to an i-th data line, and second terminals of all terminal pairs in a j-th column of terminal pairs are connected to a j-th scanning line; in the i-th row of terminal pairs, a first terminal of an o-th terminal pair is connected to a first terminal of an (o+1)-th terminal pair on a surface layer of the PCB board, and o is an odd number or an even number.

### BRIEF DESCRIPTION OF THE DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of an LED arrangement structure in the prior art;

FIG. 2 is another schematic diagram of an LED arrangement structure in the prior art;

FIG. 3 is a schematic diagram of an LED arrangement structure according to an embodiment of the present disclosure;

FIG. 4 is a schematic diagram of an LED arrangement structure according to another embodiment of the present disclosure;

FIG. 5 is a schematic diagram of an LED arrangement structure according to another embodiment of the present disclosure;

FIG. 6 is a schematic diagram of an LED arrangement structure according to another embodiment of the present disclosure;

FIG. 7 is a schematic diagram of an LED arrangement structure according to another embodiment of the present disclosure;

FIG. 8 is a schematic diagram of an LED arrangement structure according to another embodiment of the present disclosure; and

FIG. 9 is an exploded view of various film layers of the LED arrangement structure of FIG. 8.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

In the description of the present disclosure, it should be understood that orientations or position relationships indicated by the terms “center”, “lateral”, “upper”, “lower”, “left”, “right”, “vertical”, “horizontal”, “top”, “bottom”, “inside”, “outside”, “column,” “row,” and the like, are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure.

In the present disclosure, the word “some embodiments” is used to mean “serving as an example, illustration, or explanation”. Any embodiment described as exemplary in the present disclosure is not necessarily construed as being more preferable or advantageous than other embodiments. In order to enable any person skilled in the art to implement and use the present disclosure, the following description is given. In the following description, the details are listed for the purpose of explanation. It should be understood that those of ordinary skill in the art can realize that the present disclosure can also be implemented without using these specific details. In other instances, well-known structures and processes will not be elaborated to avoid unnecessary details to obscure the description of the present disclosure. Therefore, the present disclosure is not intended to be limited to the illustrated embodiments, but is consistent with the widest scope that conforms to the principles disclosed in the present disclosure.

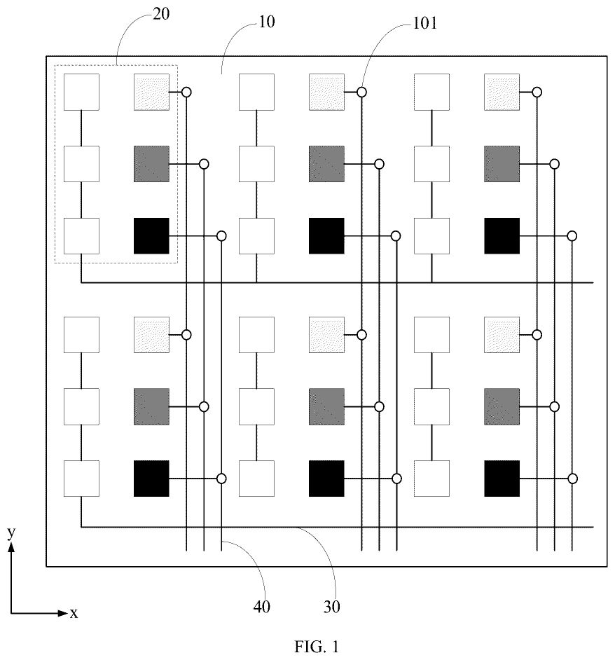

It should be noted that a first direction and a second direction mentioned in the embodiments of the present disclosure are perpendicular to each other, and the first direction may be a column direction or a row direction. Similarly, the second direction corresponds to the row direction or the column direction, and the first direction and the second direction may be interchanged in actual application. When the first direction is an x direction indicated in FIGS. 1 to 7, the second direction is a y direction indicated in FIGS. 1 to 7, the LED row is a row shown in drawings, the LED column is a column shown in drawings, the x direction in FIGS. 1 to 7 is a row direction, and the y direction is a column direction.

Referring to FIG. 1, there is shown a schematic diagram of an LED arrangement structure in the related art. As shown in FIG. 1, a plurality of light-emitting pixels 20 with the same structure are arranged on a PCB board 10 in an array manner, and each of the light-emitting pixels 20 includes three LEDs of different light-emitting colors, such as, a red LED, a blue LED, and a green LED, so that both the LEDs and the light-emitting pixels 20 are arranged on the PCB board 10 in an array manner. Common-electrode terminals of all the LEDs in each row of the light-emitting pixels 20 are electrically connected on the surface layer of the PCB board 10 to form one row scanning line, and non-common-electrode terminals of the LEDs of the same light-emitting color in each column of the light-emitting pixels 20 are electrically connected at the inner or bottom layer of the PCB board 10 through via holes 101 on the PCB board 10 to form one column data line. Here, the strobe chip performs progressive scanning of the pixels on the PCB board 10 through scanning lines 30, and the driver chip applies different currents through data lines 40 to obtain different colors in various light-emitting pixels 20, thereby obtaining a complete image on the PCB board 10.

As can be seen from FIG. 1, the number of via holes 101 in the PCB board 10 is determined by the number of LEDs, and three via holes 101 are required for each light-emitting pixel 20 to enable the data lines 40 to be led to the inner or bottom layer of the PCB board 10.

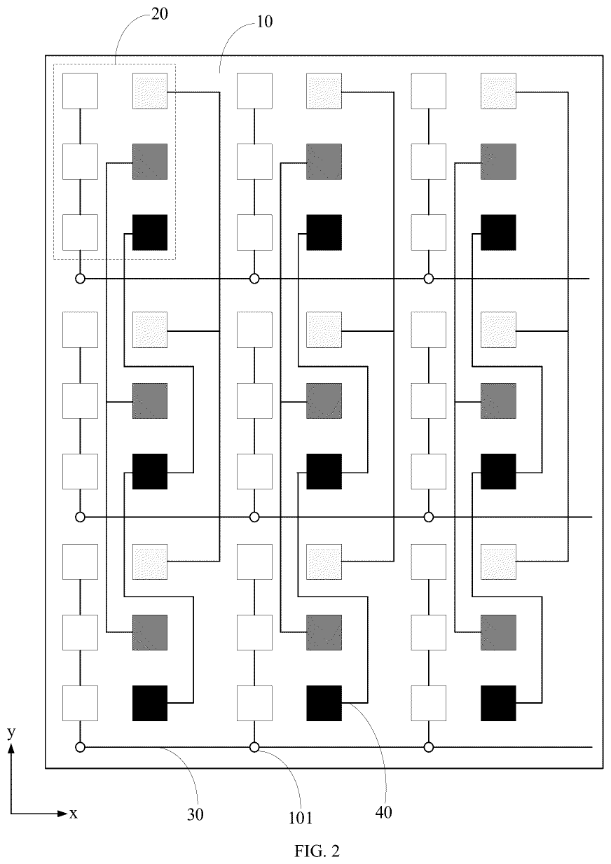

Referring to FIG. 2, FIG. 2 is a schematic diagram of another LED arrangement structure in the related art. As shown in FIG. 2, a plurality of light-emitting pixels 20 of the same structure are arranged on a PCB board 10 in an array manner, and each of the light-emitting pixels 20 includes three LEDs of different light-emitting colors, such as, a red LED, a blue LED, and a green LED, so that both the LEDs and the light-emitting pixels 20 are arranged on the PCB board 10 in an array manner. Common-electrode terminals of all the LEDs in each row of light-emitting pixels 20 are electrically connected at the inner or bottom layer of the PCB board 10 through via holes 101 in the PCB board 10 to form one row scanning line, and non-common-electrode terminals of the LEDs of the same light-emitting color in each column of light-emitting pixels 20 are electrically connected on a surface layer of the PCB board 10 to form one column data line 40.

As can be seen from FIG. 2, in order to avoid the problem of intersection of the wires on the PCB board, in each column of light-emitting pixels 20, two data lines 40 need to pass between the positive and negative electrodes of one or more LEDs. Although only one via hole 101 is required for each light-emitting pixel 20 in FIG. 2, due to the constraints of the wiring rules of the PCB board 10, the data line 40 passing between the positive and negative electrodes of the LEDs will inevitably cause the size of the LEDs to be increased, thereby causing a sharp increase in cost. As an example of the conventional COB chip 0408 (4 mil×8 mil), the distance between the positive and negative electrodes of the COB chip is only 75 μm, and generally, the pad spacing on the PCB board 10 should be designed to be smaller than the pad spacing on the COB chip to prevent the occurrence of misalignment, so the value of the pad spacing on the PCB board 10 is generally 70 μm. In accordance with the process level of the PCB board 10, the line width and the line spacing of the general wirings are both 100 μm. If two data lines 40 both pass between the positive and negative electrodes of the COB chip, the distance between the positive and negative electrodes of the COB chip is at least 500 μm. In this case, the COB chip must be much larger than the design size of the original 75 μm of the diode, which will make the diode very large and cause the manufacturing cost to increase sharply.

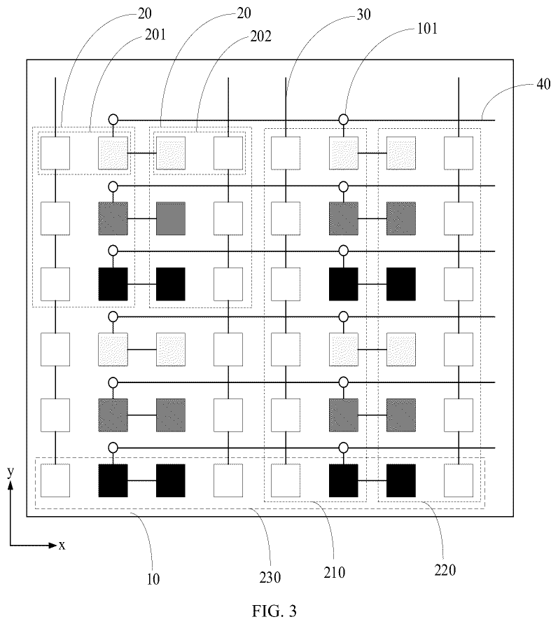

Referring to FIG. 3, there is shown a schematic diagram of an LED arrangement structure according to an embodiment of the present disclosure. As shown in FIG. 3, an LED arrangement structure includes:
a PCB board 10;
a plurality of first LEDs 201 and a plurality of second LEDs 202 disposed on the PCB board 10; the first LEDs 201 and the second LEDs 202 are arranged in a first direction and a second direction in an array manner;
the plurality of first LEDs 201 form a plurality of first LED rows 210 along the second direction, the plurality of second LEDs 202 form a plurality of second LED rows 220 along the second direction, and some of the plurality of first LEDs 201 and some of the plurality of second LEDs 202 form a plurality of third LED row 230 in the first direction;
common-electrode terminals of respective first LEDs 201 in each of the first LED rows 210 are electrically connected to form one scanning line 30; common-electrode terminals of respective second LEDs 202 in each of the second LED rows 220 are electrically connected to form one scanning line 30; non-common-electrode terminals of each of the first LEDs 201 and each of the second LEDs 202 in each of the third LED rows 230 are electrically connected to form one data line 40;
common-electrode or non-common-electrode terminals of the first LED 201 and the second LED 202 adjacent to each other in each of the third LED rows 230 are adjacent to each other; the scanning lines 30 and the data lines 40 are located in different layers in the PCB board 10.

According to the LED arrangement structure provided in the embodiment of the present disclosure, the plurality of first LEDs 201 and the plurality of second LEDs 202 are disposed on the PCB board 10, the first LEDs 201 and the second LEDs 202 are arranged in a first direction and a second direction in the array manner, the plurality of first LEDs 201 form the plurality of first LEDs rows 210 in the second direction, the plurality of second LEDs 202 form the plurality of second LED rows 220 in the second direction, and the plurality of first LEDs 201 and the plurality of second LEDs 202 form the plurality of third LED rows 230 in the first direction. At the same time, the common-electrode terminals of the first LEDs 201 in each of the first LED rows 210 are electrically connected to form one scanning line 30 in the second direction, the common-electrode terminals of the second LEDs 202 in each of the second LED rows 220 are electrically connected to form one scanning line 30 in the second direction, and the non-common-electrode terminals of the second LEDs 202 and the first LEDs 201 in each of the third LED rows 230 are electrically connected to form one data line 40 in the first direction. The common-electrode terminals or non-common-electrode terminals of the first LED 201 and the second LED 202 adjacent to each other in each of the third LED rows 230 are adjacent to each other, and the scanning line 30 and the data line 40 are located in different layers in the PCB board 10, which may not only reduce the number of via holes 101 in the PCB board 10, but also do not need to increase the width or the number of layers of the PCB board 10 additionally, and reduce the production cost of the LED display screen while increasing the yield of the PCB board 10.

Specifically, in the embodiment shown in FIG. 3, three adjacent first LEDs 201 in the first LED row 210 may form one light-emitting pixel 20, and three adjacent second LEDs 202 in the second LED row 220 may form one light-emitting pixel 20. The first LEDs 201 in the light-emitting pixel 20 are vertically arranged, and the second LEDs 202 in the light-emitting pixel 20 are similarly vertically arranged. The scanning line 30 formed by electrically connecting the common-electrode terminals of the first LEDs 201 in each of the first LED rows 210 is a column scanning line, the scanning line 30 formed by electrically connecting the common-electrode terminals of the second LEDs 202 in each of the second LED rows 220 is also a column scanning line, and the date line 40 formed by electrically connecting the non-common-electrode terminals of the first LEDs 201 and the second LEDs 202 in each of the third LED rows 230 is a row data line. Since the common-electrode terminals or the non-common-electrode terminals of the first LED 201 and the second LED 202 adjacent to each other in each of the third LED rows 230 are adjacent to each other, the LEDs in at least the first LED rows 210 or the second LED rows 220 may not be provided with the via holes 101 in the PCB board 10, and each of the LEDs is not required to be provided with a via hole 101 in the PCB board Therefore, the number of the via holes 101 in the PCB board 10 is reduced without increasing the size of the LED and the width or thickness of the PCB board 10, thereby reducing the production cost of the LED display screen while improving the yield of the PCB board 10.

In some embodiments, each of the scanning lines 30 is disposed on the surface layer of the PCB board 10, and each of the data lines 40 is disposed on the bottom or inner layer of the PCB board 10. Specifically, the scanning line 30 formed by electrically connecting the common-electrode terminals of the first LEDs 201 in each of the first LED rows 210 is disposed on the surface layer of the PCB board 10, the scanning line 30 formed by electrically connecting the common-electrode terminals of the second LEDs 202 in each of the second LED rows 220 is also disposed on the surface layer of the PCB BOARD 10, and the data line 40 formed by electrically connecting the non-common-electrode terminals of the first LEDs 201 and the second LEDs 202 in each of the third LED rows 230 is disposed on the bottom layer or the inner layer of the PCB board 10.

In some embodiments, several adjacent first LEDs 201 in each of the first LED rows 210 constitute one light-emitting pixel 20, and several adjacent second LEDs 202 in each of the second LED rows 220 constitute one light-emitting pixel 20. Specifically, one light-emitting pixel 20 may be formed by a plurality of LEDs, one or more LEDs having the same or different light-emitting colors may be present in the one light-emitting pixel 20, the two light-emitting pixels 20 may or may not be completely the same in terms of the size, number, and color of the LEDs, and a specific arrangement thereof may be configured according to an actual application.

In some embodiments, the first LEDs 201 and the second LEDs 202 in each of the third LED rows 230 are LEDs of the same light-emitting color; the first LED 201 and the second LED 202 are LEDs of the same size; the first LED 201 and the second LED 202 are any one of red LEDs, blue LEDs, and green LEDs. However, the embodiments of the present disclosure are not limited thereto, the first LEDs 201 and the second LEDs 202 may be LEDs of different sizes.

Specifically, in the present embodiment, all light-emitting pixels 20 are identical to each other, and each of the light-emitting pixels 20 is composed of a red LED, a blue LED, and a green LED. The red LED, the blue LED, and the green LED are vertically arranged from top to bottom in the second direction in sequence, so that the left and right viewing angles of the LED display screens are symmetrical, and the left and right viewing angles of the LED display screens formed into a finished product are maximized.

Specifically, each of the light-emitting pixels 20 may be composed of the red LED, the blue LED, and the green LED. Similarly, the light-emitting pixels 20 formed on the PCB board 10 by the first LEDs 201 and the second LEDs 202 are arranged on the PCB board 10 in the array manner. The red LED, the blue LED, and the green LED in each of the light-emitting pixels 20 may be vertically arranged from top to bottom in sequence.

It should be noted that the first LEDs 201 and the second LEDs 202 in each of the third LED row 230 may be LEDs of the same size, or may be LEDs of different sizes, as long as the left and right positions of the common-electrode and non-common-electrode terminals of the second LED 202 in the first LED row 210 and the second LED row 220 that are adjacent to each other are reversed as shown in FIG. 3, so that the via holes 101 in at least one column on the PCB board 10 may be omitted.

In some embodiments, the non-common-electrode terminals of the first LED 201 and the second LED 202 that are adjacent to each other in each of the third LED rows 230 are electrically connected at the surface layer of the PCB board 10. Specifically, when the common-electrode terminals of the first LED 201 and second LED 202 that are adjacent to each other in each of the third LED rows 230 are adjacent to each other, if there is only one corresponding first LED row 210 on the PCB board 10, the first LED row 210 cannot be placed at the outermost edge of the array and needs to be arranged in the middle of the array; if there is only one corresponding second LED row 220 on the PCB board 10, the second LED row 220 cannot be placed at the outermost edge of the array and needs to be arranged in the middle of the array. In this case, the electrical connection between the non-common-electrode terminals of the first LED 201 and the second LED 202 that are adjacent to each other in the third LED row 230 on the surface layer of the PCB board 10 can be realized, thereby reducing the number of via holes 101 on the PCB board 10. When the non-common-electrode terminals of the first LED 201 and second LED 202 that are adjacent to each other in each of the third LED rows 230 are adjacent to each other, the electrical connection between the non-common-electrode terminals of the first LED 201 and second LED 202 that are adjacent to each other in the third LED row 230 can be directly realized on the surface layer of the PCB board 10, thereby reducing the number of via holes 101 on the PCB board 10.

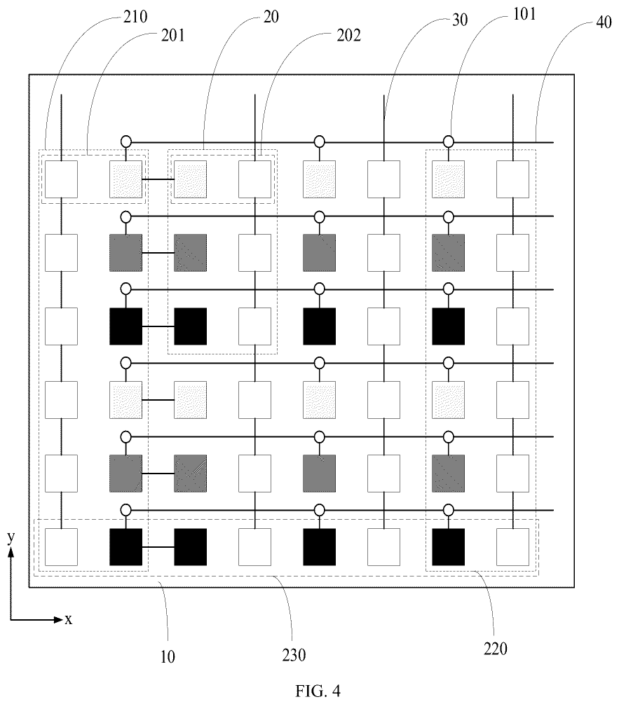

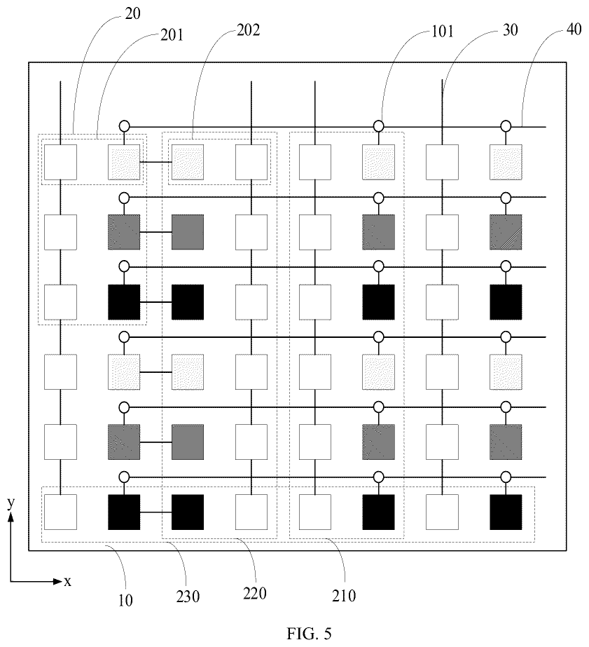

In some embodiments, as shown in FIGS. 3 to 5, the number of the first LED rows 210 and the number of the second LED rows 220 on the PCB board 10 may or may not be equal, the first LED rows 210 and the second LED rows 220 may or may not be arranged alternately on the PCB board 10, and the number of via holes 101 on the PCB board 10 may be reduced only if the common-electrode or non-common-electrode terminals of the first LED 201 and second LED 202 that are adjacent to each other in each of the third LED rows 230 are adjacent to each other. In FIG. 3, the number of the first LED rows 210 is equal to the number of the second LED rows 220, and the first LED rows 210 and the second LED rows 220 are alternately arranged on the PCB board 10, so that half of the via holes 101 on the PCB board 10 can be omitted with respect to FIG. 1. The number of the first LED rows 210 in FIG. 4 is less than the number of the second LED rows 220. If the number of the first LED rows 210 is a and the number of the second LED rows 220 is b, the via holes 101 of the a rows can be omitted from the PCB board 10 in FIG. 1. In FIG. 5, the number of the first LED rows 210 is greater than the number of the second LED rows 220. If the number of the first LED rows 210 is a and the number of the second LED rows 220 is b, the via holes 101 of the b rows may be omitted from the PCB board 10 in FIG. 1.

In some embodiments, the non-common-electrode terminals of all the first LEDs 201 in each of the third LED rows 230 are electrically connected to each other through via holes 101 on the PCB board 10. Specifically, as shown in FIG. 3, when the non-common-electrode terminals of all the first LEDs 201 in the third LED row 230 are electrically connected to each other through the via holes 101 on the PCB board 10, it is only necessary to electrically connect the non-common-electrode terminal of the second LED 202 adjacent to the first LED 201 with the non-common-electrode terminal of the first LED 201 on the surface layer of the PCB board 10, so as to reduce the number of the via holes 101 on the PCB board 10.

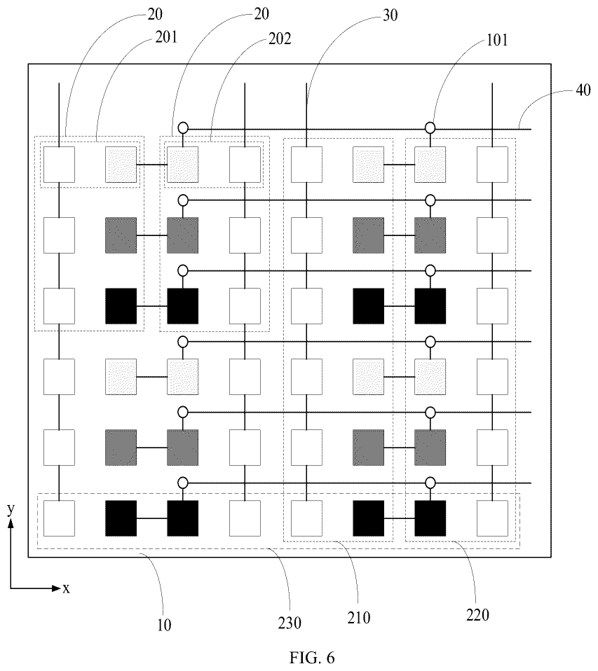

In some embodiments, the non-common-electrode terminals of all the second LEDs 202 in each of the third LED rows 230 are electrically connected to each other through via holes 101 on the PCB board 10. Specifically, as shown in FIG. 6, when non-common-electrode terminals of all second LEDs 202 in a third LED row 230 are electrically connected to each other through the via holes 101 on the PCB board 10, it is only necessary to electrically connect a non-common-electrode terminal of a first LED 201 adjacent to a second LED 202 with a non-common-electrode terminal of the second LED 202 on the surface layer of the PCB board 10, so as to reduce the number of the via holes 101 in the PCB board 10.

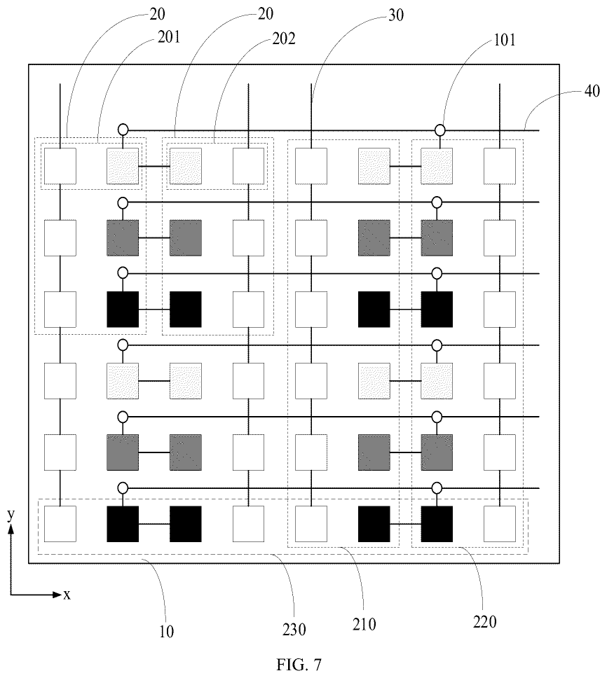

In some embodiments, the non-common-electrode terminals of the first LED 201 and the second LED 202 in each of the third LED rows 230 are electrically connected to each other through the via hole 101 on the PCB board 10. Specifically, as shown in FIG. 7, when non-common-electrode terminals of a first LED 201 and a second LED 202 in a third LED row 230 are electrically connected to each other through a via hole 101 on the PCB board 10, a non-common-electrode terminal of a second LED 202 adjacent to the first LED 201 is electrically connected to the non-common-electrode terminal of the first LED 201 on the surface layer of the PCB board 10, and a non-common-electrode terminal of a first LED 201 adjacent to the second LED 202 is electrically connected to the non-common-electrode terminal of the second LED 202 on the surface layer of the PCB board 10, thereby reducing the number of via holes 101 on the PCB board 10.

It may be appreciated that one first LED 201 in the third LED row 230 corresponds to a single first LED row 210, and one second LED 202 corresponds to a single second LED row 220. The first LED rows 210 and the second LED rows 220 are arranged in the first direction, and the third LED rows 230 are arranged in the second direction.

It may also be appreciated that the arrangement of the LEDs in FIGS. 3 to 7 may be rotated by 90 degrees in practical applications, i.e., the column scanning lines formed in FIGS. 3 to 7 become row scanning lines, the row data lines become column data lines, and the LEDs in each of the light-emitting pixels 20 are arranged horizontally.

It may also be appreciated that the LEDs 201 in the LED lamp panel structure provided in the embodiments of the present disclosure may be packaged on the PCB board 10 in a COB (Chip On Board) manner, or may be packaged on the PCB board 10 in a SMD (Surface Mounted Devices) manner, which may be selected according to the specific situation in the actual application, and is not specifically limited in the present disclosure.

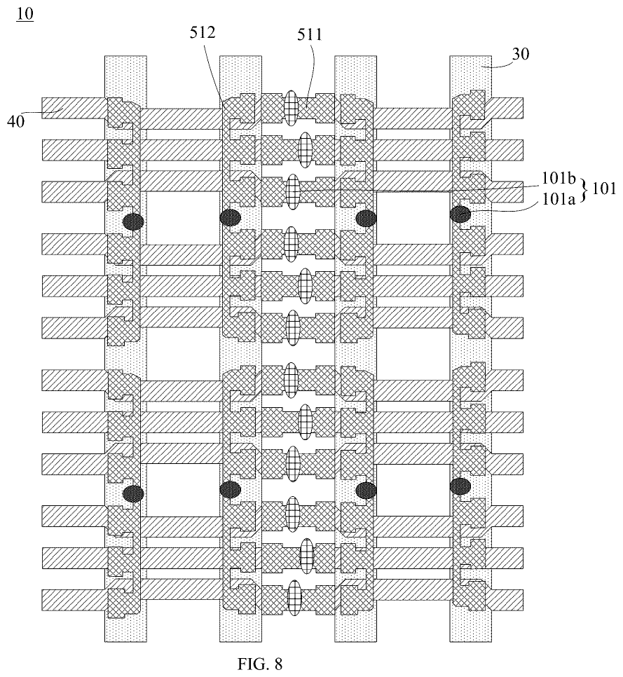

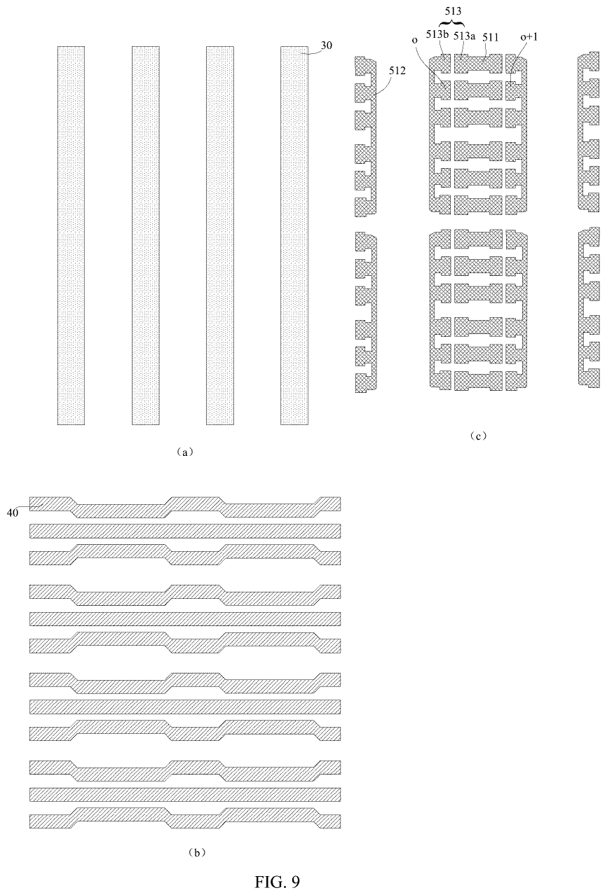

Based on the above description, it may be appreciated that the scanning line 30 necessarily includes a portion on the PCB board 10 and a portion on the LED. The data line 40 necessarily includes a portion on the PCB board 10. The via hole 101 is used to connect respective portions of different film layers. In connection with the above description, the structure of the PCB board 10 can be determined, and FIGS. 8 and 9 are provided to illustrate the structure of the PCB board 10. The LED arrangement structure provided in the embodiments of the present disclosure will be further described in connection with the structure of the PCB board 10.

Figure (a) of FIG. 9 is an exploded view of the film layer in which the scanning lines are located in the LED arrangement structure in FIG. 8. (B). Figure (b) of FIG. 9 is an exploded view of the film layer in which the data lines are located in the LED arrangement structure in FIG. 8. Figure (c) in FIG. 9 is an exploded view of the film layer in which the non-common-electrode connection wires are located in the LED arrangement structure in FIG. 8.

It should be noted that, in FIGS. 8 and 9, the non-common-electrode connection line 511 and the common-electrode connection line 512 are located in the same film layer, and the scanning line 30, the data line 40, and the non-common-electrode connection line 511 are located in different film layers. However, the embodiment of the present disclosure is not limited thereto, for example, the non-common-electrode connection line and the common-electrode connection line are located in different film layers.

As shown in FIGS. 3 to 9, an embodiment of the present disclosure provides an LED arrangement structure including a PCB board 10 and a plurality of LEDs disposed on the PCB board 10.

The PCB board 10 is provided with a plurality of data lines 40 extending in a first direction, a plurality of scanning lines 30 extending in a second direction, and a plurality of via holes 101 in a display area of the PCB board 10. The data lines 40 and the scanning lines 30 are located at different layers of the PCB board 10, and the second direction intersects the first direction. The plurality of via holes 101 includes a plurality of first via holes 101a and a plurality of second via holes 101b.

The plurality of LEDs (e.g., a first LEDs 201) are disposed on the PCB board, the plurality of LEDs are arranged in an array in the first direction and the second direction, so as to form a plurality of rows of LEDs (e.g., a third LED row 230) and a plurality of columns of LEDs (e.g., a first LED row 210). The rows of LEDs extend in the first direction, and the columns of LEDs extend in the second direction. Each of the LED rows includes a plurality of LED groups (e.g., as shown in FIG. 3, the first LED 201 and the second LED 202 form one LED group), and each of the LED groups includes two adjacent LEDs. A plurality of adjacent LEDs are sequentially arranged in the second direction to form a plurality of light emitting pixels. The LED includes a common-electrode terminal and a non-common-electrode terminal.

In each of the LED columns, common-electrode terminals of all the LEDs are connected to one of the scanning lines 30 through first via holes 101a.

In each of the LED rows, non-common-electrode terminals of all the LEDs are connected to one of the data lines 40.

In at least one of the LED rows, the non-common-electrode terminals of the two LEDs in each of the LED groups are connected to each other on the surface layer of the PCB board 10.

According to the embodiment of the present disclosure, two non-common-electrode terminals in each of the LED groups are connected to each other on the surface layer of the PCB board in at least one LED row, so that when the LEDs are connected to the PCB board, the two LEDs of which the non-common-electrode terminals are connected to each other can be connected to the PCB board through one via hole, thereby reducing the number of via holes on the PCB board, improving the yield of the PCB board, and reducing the production cost of the PCB board.

Specifically, compared with a case where each of the non-common-electrode terminals of the LED lamp leads in the related art is connected to the PCB board through the via hole, in the embodiments of the present disclosure, the non-common-electrode terminals of the two LEDs in each LED group are connected to each other on the surface layer of the PCB board, so that when the via holes are provided, the number of via holes can be reduced, and the connection positions between the non-common-electrode terminals and the data lines can be reduced, thereby reducing the risk of connection failure, improving the yield of the PCB board, and reducing the production cost of the PCB board.

In some embodiments, as shown in FIGS. 8 and 9, a plurality of non-common-electrode connection lines 511 extending in the first direction are further provided in the display area of the PCB board 10, the non-common-electrode connection lines 511 and the data lines 40 are located at different layers of the PCB board 10, and the non-common-electrode connection lines 511 and the scanning lines 30 are located at different layers of the PCB board 10. In each of the LED groups, non-common-electrode terminals of two LEDs are connected to one of the non-common-electrode connection lines 511. By arranging the non-common-electrode connection lines so that the non-common-electrode connection lines are located at different layers from the data lines and the scanning lines, the size of a single line can be reduced, thereby reducing the size of the pixel. Accordingly, the resolution of the LED arrangement structure can be improved. By connecting the non-common-electrode terminals of the two LEDs to one non-common-electrode connection line, the number of via holes in the PCB board can be reduced, and the number of via holes in the LED arrangement structure can be reduced, thereby improving the yield of the LED arrangement structure.

Specifically, as shown in FIGS. 3 and 8, it can be seen that in one of the LED groups, the non-common-electrode terminals of two LEDs (for example, the first LED 201 and the second LED 202 in FIG. 3) are connected together, so that the non-common-electrode terminals of the two LEDs can be connected to one non-common-electrode connection line 511, thereby reducing the number of via holes and increasing the yield of the LED arrangement structure.

In some embodiments, as shown in FIGS. 8 and 9, the non-common-electrode connection line 511 is connected to the data line 40 through the second via hole 101b. By connecting the non-common-electrode connection line through the second via hole to the data line, the data line can be used to drive the LEDs through the non-common-electrode connection line, so that normal operation of the LED arrangement structure is realized.

In some embodiments, in each of the LED groups, the non-common-electrode connection line is connected to one of the data lines through at least one second via hole. Specifically, the non-common-electrode connection line may be connected to one of the data lines through one second via hole, the non-common-electrode connection line may be connected to one of the data lines through two second via holes, or the non-common-electrode connection line may be connected to one of the data lines through three via holes.

In some embodiments, as shown in FIGS. 8 and 9, in each of the LED groups, the non-common-electrode connection line 511 is connected to one of the data lines 40 through at least one, and at most two, second via holes 101b. The number of the second via holes in the PCB board is relatively small by connecting the non-common-electrode connection line to one data line through one second via hole, so that the space occupied by a single pixel is reduced, the resolution of the LED arrangement structure is improved, and the number of the via holes is reduced to reduce damage to each film layer of the PCB board in a process, thereby avoiding the effects of moisture and oxygen invasion, electrical change, and the like, and improving the yield of the PCB board. By connecting the non-common-electrode connection line to one data line through two second via holes, when the wiring in one of the two second via holes is broken, the wiring in another of the two second via holes can still turn on two LEDs, thereby increasing the yield of the PCB board.

Specifically, as shown in FIG. 8, in each of the LED groups, the non-common-electrode connection line 511 is connected to one of the data lines through one second via hole 101b.

The common-electrode terminal of each LED is connected to the scanning line through a via hole, so that the number of via holes is too large, the size of the pixel becomes larger, and the yield of the LED arrangement structure becomes lower. In view of the above problems, in some embodiments, as shown in FIGS. 3 and 8, the common-electrode terminals of all LEDs of the light-emitting pixel 20 are connected to the scanning line 30 through one first via hole 101a. By connecting the common-electrode terminals of all the LEDs of the light-emitting pixel to the scanning line through one via hole, the number of via holes can be reduced, so that the size of the pixel can be reduced, the resolution of the LED arrangement structure can be improved, and the yield of the LED arrangement structure can be improved. In some embodiments, as shown in FIGS. 3, 8, and 9, the common-electrode terminals of all LEDs in at least two adjacent light-emitting pixels 20 in each of the LED columns are connected to the scanning line 30 through one first via hole 101a. By connecting the common-electrode terminals of all the LEDs in the two adjacent light-emitting pixels to the scanning line through one first via hole, the number of via holes on the PCB board can be reduced, so that the size of the pixels can be reduced, the resolution of the LED arrangement structure can be improved, and the yield of the LED arrangement structure can be improved.

It should be noted that, in FIGS. 8 and 9, although only a first terminal 513a or a second terminal 513b is shown in a part of terminal pairs 513, it may be understood that there may be a second terminal 513b corresponding to the first terminal 513a to form a terminal pair 513, and there may be a first terminal constituting the 513a corresponding to the second terminal 513b to form a terminal pair 513. Therefore, in the following embodiment, the first terminal 513a or the second terminal 513b is still described as a portion of one terminal pair 513. Accordingly, the terminal pair 513 shown in FIGS. 8 and 9 is a third column terminal pair and a fourth column terminal pair, and the scanning lines shown in FIGS. 8 and 9 are a second scanning line, a third scanning line, a fourth scanning line, and a fifth scanning line.

It should be noted that in FIG. 9, the third terminal pair and the fourth terminal pair in the second row are used as an example for description, and therefore, o is 3. However, the embodiment of the present disclosure is not limited thereto, and o may be a corresponding value depending on the position of the terminal pair.

Meanwhile, as shown in FIGS. 3 to 9, an embodiment of the present disclosure provides an LED arrangement structure including a PCB board 10 for mounting a plurality of LEDs. The PCB board 10 includes M data lines 40, N scan lines 30 and a plurality of terminal pairs 513.

The M (where M≥3 and is an integer) data lines 40 extend in the first direction.

The N (where N≥2 and is an integer) scan lines 30 extend in the second direction. The second direction intersects the first direction.

The plurality of terminal pairs 513 are disposed on a surface layer of the PCB board 10. Each of the plurality of terminal pairs 513 includes a first terminal 513a and a second terminal 513b. The plurality of terminal pairs 513 form M rows of terminal pairs 513 and N columns of terminal pairs 513. The first terminals 513a of all the terminal pairs 513 in an i-th row of terminal pairs 513 are connected to an i-th data line 40, and the second terminals 513b of all the terminal pairs 513 in a j-th column of terminal pairs 513 are connected to a j-th scanning line 30. For example, in FIGS. 8 and 9, the first terminals 513a of all the terminal pairs 513 in a second row of terminal pairs 513 are connected to a second data line, and the second terminals 513b of all the terminal pairs 513 in a third column of terminal pairs 513 are connected to a third scanning line.

In the i-th row of terminal pairs 513, the first terminal 513a of an o-th (o is an odd number or an even number) terminal pair 513 is connected to the first terminal 513a of an (o+1)-th terminal pair 513 on the surface layer of the PCB board. For example, in FIGS. 8 and 9, in the second row of terminal pairs, the first terminal 513a of a third terminal pair 513 is connected to the first terminal 513a of a fourth terminal pair 513 on the surface layer of the PCB board 10.

Embodiments of the present disclosure provide an LED arrangement structure, in which in one row of terminal pairs, a first terminal of a previous terminal pair is connected to a first terminal of a next terminal pair, so that two LEDs can be connected through the first terminals of two terminal pairs, and the two LEDs can be connected to the PCB board through one via hole, thereby reducing the number of via holes on the PCB board, improving the yield of the PCB board, and reducing the production cost of the PCB board.

In some embodiments, as shown in FIGS. 8 and 9, the PCB board 10 further includes M*N/2 non-common-electrode connection lines 511 arranged in an array, and M*N/2 is an integer. The non-common-electrode connection lines 511 extend in a first direction, the non-common-electrode connection lines 511 are located on a surface layer of the PCB board 10, the scanning lines 30 are located on an inner layer or a bottom layer of the PCB board 10, and the data lines 40 are located on a film layer between the non-common-electrode connection lines 511 and the scanning lines 30. In the i-th row of terminal pairs 513, the first terminal 513a of the o-th terminal pair 513 is connected to the first terminal 513a of the (o+1)-th terminal pair through the p-th non-common-electrode connection line 511 in the i-th row. When o is an even number, p is o/2, and when o is an odd number, p is (o+1)/2. By connecting the first terminals of the two terminal pairs through the non-common-electrode connection line, the two LEDs can be connected through the first terminals of the two terminal pairs, and the two LEDs can be connected to the PCB board through one via hole, so that the number of via holes on the PCB board can be reduced, thereby improving the yield of the PCB board and reducing the production cost of the PCB board. However, the embodiment of the present disclosure is not limited to this, and the scanning line may be located on the film layer between the non-common-electrode connection line and the data line.

Specifically, for example, the third terminal pair and the fourth terminal pair are shown in FIGS. 8 and 9, a first terminal 513a of the third terminal pair 513 in a second row is connected to a first terminal 513a of the fourth terminal pair 513 through a second non-common-electrode connection line 511 (a first non-common-electrode connection line is not shown in FIG. 8) in the second row.

In some embodiments, as shown in FIGS. 8 and 9, a p-th non-common-electrode connection line 511 in an i-th row is connected to an i-th data line 40 through at least one and at most two via holes. The non-common-electrode connection line is connected to the data line through one via hole, so that the number of via holes in the PCB board is small, the space occupied by a single pixel is reduced, the resolution of the LED arrangement structure is improved, reducing of the number of via holes may reduce the damage to each film layer of the PCB board in the process, the influences of moisture-oxygen invasion, electric change and the like are avoided, and the yield of the PCB board is improved. By connecting the non-common-electrode connection lines to one data line through two via holes, when the wiring in one of the two via holes is broken, the wiring in another of the two via holes can still turn on two LEDs, thereby improving the yield of the PCB board.

Specifically, as shown in FIGS. 8 and 9, the second non-common-electrode connection line 511 in the second row is connected to the second data line 40 through one second via hole 101b. However, the embodiment of the present disclosure is not limited to this, and it is possible to connect the data line through a plurality of via holes to the non-common-electrode connection line.

In some embodiments, as shown in FIGS. 8 and 9, the PCB board 10 further includes M*N/3 common-electrode connection lines 512 arranged in an array, and M*N/3 is an integer. The common-electrode connection lines 512 are located on a surface layer of the PCB board 10. The j-th column of terminal pairs 513 includes a plurality of repeating units, and the second terminals 513b of all the terminal pairs 513 in the same repeating unit are connected by one of the common-electrode connection lines 512, the common-electrode connection line 512 is connected to the j-th scanning line 30 by a via hole. The second terminals of all terminal pairs in the repeating unit are connected to each other through one common-electrode connection line, and the common-electrode connection line is connected to the scanning line through the via hole, so that the common-electrode terminals of all the LEDs of the light-emitting pixel are connected to the scanning line through one via hole, thereby reducing the number of via holes, reducing the size of the pixel, and improving the resolution and yield of the LED arrangement structure.

Specifically, two common-electrode connection lines in two adjacent repeating units may be connected to the scanning line through the same via hole.

In the specific implementation, each of the above units or structures may be implemented as a separate object, or may be implemented in any combination as the same object or several objects. For a specific implementation of each of the above units or structures, reference may be made to the foregoing embodiments, and details are not described herein.

The LED arrangement according to an embodiment of the present disclosure have been described in detail. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of application in accordance with the teachings of the present disclosure. In view of the foregoing, the content of the present specification should not be construed as limiting the disclosure.

What is claimed is:

1. A light-emitting diode (LED) arrangement structure comprising:
a PCB board, wherein a plurality of data lines extending in a first direction, a plurality of scanning lines extending in a second direction, and a plurality of via holes are disposed in a display region of the PCB board; the plurality of data lines and the plurality of scanning lines are located on different layers of the PCB board, and the second direction intersects the first direction; and the plurality of via holes include a plurality of first via holes and a plurality of second via holes; and
a plurality of LEDs disposed on the PCB board, wherein the plurality of LEDs are arranged in an array in the first direction and the second direction to form a plurality of LED rows and a plurality of LED columns, the LED rows extend in the first direction, and the LED columns extend in the second direction; each of the LED rows includes a plurality of LED groups, and each of the LED groups includes two adjacent LEDs; a plurality of adjacent LEDs are sequentially arranged in the second direction to form a plurality of light-emitting pixels; and each of the LEDs includes a common-electrode terminal and a non-common-electrode terminal,
wherein common-electrode terminals of all LEDs in each of the LED columns are connected to a corresponding one of the scanning lines through one or more first via holes of the first via holes;
non-common-electrode terminals of all LEDs in each of the LED rows are connected to a corresponding one of the data lines; and
non-common-electrode terminals of two LEDs in each of LED groups in at least one of the LED rows are connected to each other on a surface layer of the PCB board.

2. The LED arrangement structure according to claim 1, wherein a plurality of non-common-electrode connection lines extending in the first direction are further provided in the display area of the PCB board, the non-common-electrode connection lines and the data lines are located at different layers of the PCB board, and the non-common-electrode connection lines and the scanning lines are located at different layers of the PCB board; and the non-common-electrode terminals of the two LEDs in each of the LED groups are connected to a corresponding one of the non-common-electrode connection lines.

3. The LED arrangement structure according to claim 2, wherein each of the non-common-electrode connection lines is connected to a corresponding one of the data lines through a corresponding second via hole of the second via holes.

4. The LED arrangement structure according to claim 3, wherein in each of the LED groups, the corresponding one of the non-common-electrode connection lines is connected to a corresponding one of the data lines through at least one second via hole.

5. The LED arrangement structure according to claim 1, wherein common-electrode terminals of all LEDs in each of the light-emitting pixels are connected to a corresponding one of the scanning lines through a corresponding one of the first via holes.

6. The LED arrangement structure according to claim 1, wherein in each of the LED columns, common-electrode terminals of all LEDs of at least two adjacent light-emitting pixels are connected to a corresponding one of the scanning lines through a corresponding one of the first via holes.

7. The LED arrangement structure according to claim 2, wherein the non-common-electrode terminals of the two LEDs in each of the LED groups are adjacent to each other in the first direction, and the non-common-electrode connection lines are located on the surface layer of the PCB board.

8. The LED arrangement structure according to claim 1, wherein all the LEDs in each of the LED rows are LEDs with the same light-emitting color.

9. The LED arrangement structure according to claim 1, wherein the LEDs comprise a plurality of red LEDs, a plurality of blue LEDs, and a plurality of green LEDs.

10. The LED arrangement structure according to claim 1, wherein each of the light-emitting pixels comprises a red LED, a blue LED and a green LED.

11. The LED arrangement structure according to claim 1, wherein the LEDs are encapsulated on the PCB board in a COB manner or an SMD manner.

12. A light-emitting diode (LED) arrangement structure comprising a PCB board for mounting a plurality of LEDs, wherein the PCB board comprises:
M data lines extending in a first direction, wherein M≥3 and is an integer;
N scanning lines extending in a second direction, wherein N≥2 and is an integer; and the second direction intersects the first direction; and
a plurality of terminal pairs, wherein each of the terminal pairs includes a first terminal and a second terminal, the plurality of terminal pairs form M rows of terminal pairs and N columns of terminal pairs, first terminals of all terminal pairs in an i-th row of terminal pairs are connected to an i-th data line, and second terminals of all terminal pairs in a j-th column of terminal pairs are connected to a j-th scanning line;
wherein in the i-th row of terminal pairs, a first terminal of an o-th terminal pair is connected to a first terminal of an (o+1)-th terminal pair on a surface layer of the PCB board, and o is an odd number or an even number.

13. The LED arrangement structure according to claim 12, wherein the PCB board further comprises M*N/2 non-common-electrode connection lines arranged in an array, and M*N/2 is an integer; the non-common-electrode connection lines extend in the first direction, the non-common-electrode connection lines are located on the surface layer of the PCB board, the scanning lines are located on an inner layer or a bottom layer of the PCB board, and the data lines are located on a film layer between the non-common-electrode connection lines and the scanning lines; in the i-th row of terminal pairs, the first terminal of the o-th terminal pair is connected to the first terminal of the (o+1)-th terminal pair through a p-th non-common-electrode connection line in the i-th row; and under a case where o is the even number, p is o/2, and under a case where o is the odd number, p is (o+1)/2.

14. The LED arrangement structure according to claim 13, wherein the p-th non-common-electrode connection line in the i-th row is connected to the i-th data line through at least one via hole.

15. The LED arrangement structure according to claim 12, wherein the PCB board further comprises M*N/3 common-electrode connection lines arranged in an array, and M*N/3 is an integer; the common-electrode connection lines are located on the surface layer of the PCB board; the j-th column of terminal pairs includes a plurality of repeating units, and second terminals of all terminal pairs in a same repeating unit are connected to each other through a corresponding one of the common-electrode connection lines, and the corresponding one of the common-electrode connection lines is connected to the j-th scanning line through a via hole.

16. The LED arrangement structure according to claim 12, wherein the first terminal of the o-th terminal pair and the first terminal of the (o+1)-th terminal pair are adjacent to each other in the first direction.

17. The LED arrangement structure according to claim 12, wherein the LEDs comprise a plurality of red LEDs, a plurality of blue LEDs, and a plurality of green LEDs.

18. The LED arrangement structure according to claim 12, wherein the LEDs are encapsulated on the PCB board in a COB manner or an SMD manner.
